(19) United States
(12) Patent Application Publication
(10) Pub. No.: US 2014/0043130 A1
(43) Pub. Date: Feb. 13, 2014

(54) PLANAR ELECTRONIC DEVICE

(71) Applicants: Sidharth Dalmia, Fair Oaks, CA (US); Mark Patrick McGrath, West Sacramento, CA (US); Sun Zhuowen, Sacramento, CA (US); Khanh Nguyen, Davis, CA (US)

(72) Inventors: Sidharth Dalmia, Fair Oaks, CA (US); Mark Patrick McGrath, West Sacramento, CA (US); Sun Zhuowen, Sacramento, CA (US); Khanh Nguyen, Davis, CA (US)

(73) Assignee: Tyco Electronics Corporation, Berwyn, PA (US)

(21) Appl. No.: 13/572,318

(22) Filed: Aug. 10, 2012

(51) Int. Cl. H01F 5/00; H03H 7/01; H03H 7/42

(52) U.S. Cl. 336/200; 333/25; 333/24 R

(57) ABSTRACT

A planar electronic device includes top conductors on a top side of a planar substrate connected to conductive vias and defining top conductor groups and bottom conductors on a bottom side connected to corresponding vias and defining bottom conductor groups. The conductors and vias define primary and secondary conductive loops with the top conductor group including at least one primary top conductor and at least one secondary top conductor and with the bottom conductor group including at least one primary bottom conductor and at least one secondary bottom conductor. The top conductors within each group have substantially similar layouts that are different from layouts of the immediately adjacent groups, and the bottom conductors within each group have substantially similar layouts that are different from layouts of the immediately adjacent groups.

### BACKGROUND OF THE INVENTION

The subject matter herein relates generally to planar electronic devices, such as transformers, inductors, baluns, couplers, or filters.

Some known electronic devices include planar bodies, such as circuit boards, that include one or more magnetic components built into the planar bodies. The magnetic component can include a ferrite core with conductive winding extending around the ferrite core. Some of these magnetic components include two conductive windings that are not conductively coupled with each other. For example, the conductive windings may not be physically or mechanically coupled such that electric current cannot flow through one conductive winding directly onto the other conductive winding. The current flowing through one winding generates a magnetic field in the core and in the other winding. The magnetic field in the other winding generates an electric current in the other winding. The electrical performance of the device can be determined by a variety of parameters, such as the ratio of the number of turns in the first winding to the number of turns in the second winding, the shape of the first and/or second windings, the impedance of the first and second windings, and the like.

The conductive windings typically include top conductors, bottom conductors, and conductive vias therebetween. Some planar electronic devices include circular ferrite cores, while other planar electronic devices include non-circular ferrite cores. The size and shape of the ferrite cores has an effect on density of the conductive windings as well as the layout of the conductive windings. Typically, the conductors making the windings are closely spaced to maximize capacitive coupling between adjacent windings. The layout of such conductors may have adjacent primary and secondary sections that are different (e.g. one short and one long), which negatively affects the performance of the planar electronic device.

Moreover the vias that connect top to bottom conductors may not be staggered or repeated inside the core for symmetry causing the lengths to be unequal. Additionally, some conductors suffer from degraded signals, such as from return loss. Furthermore, particularly at high frequency, planar electronic devices have poor performance compared to wired counterparts due to less primary and secondary capacitance.

A need exists for planar electronic devices having increased performance

### BRIEF DESCRIPTION OF THE INVENTION

In one embodiment, a planar electronic device is provided that includes a planar substrate having a cavity configured to receive a ferrite material body therein. The planar substrate has a top side and a bottom side. Conductive vias extend through the substrate. Top conductors are provided on the top side of the planar substrate electrically connected to corresponding conductive vias with adjacent top conductors defining top conductor groups. Bottom conductors are provided on the bottom side of the planar substrate electrically connected to corresponding conductive vias with adjacent bottom conductors defining bottom conductor groups. The top conductors, bottom conductors and conductive vias define a primary conductive loop and a secondary conductive loop with the top conductor group including at least one top conductor of the primary conductive loop and at least one top conductor of the secondary conductive loop and with the bottom conductor group including at least one bottom conductor of the primary conductive loop and at least one bottom conductor of the secondary conductive loop. The top conductors within each group have substantially similar layouts that are different from layouts of the top conductors of the immediately adjacent groups, and the bottom conductors within each group have substantially similar layouts that are different from layouts of the bottom conductors of the immediately adjacent groups.

In another embodiment, a planar electronic device is provided including a planar substrate having a cavity configured to receive a ferrite material body therein. The planar substrate has a top side and a bottom side. Conductive vias extend through the substrate. Top conductors are provided on the top side of the planar substrate electrically connected to corresponding conductive vias with adjacent top conductors defining top conductor groups. The top conductors each have a first edgeside facing the adjacent top conductor within the corresponding group and a second edgeside facing the adjacent top conductor within the adjacent group. Bottom conductors are provided on the bottom side of the planar substrate electrically connected to corresponding conductive vias. The top conductors, bottom conductors and conductive vias define a primary conductive loop and a secondary conductive loop. The top conductor group includes at least one top conductor of the primary conductive loop and at least one top conductor of the secondary conductive loop. The bottom conductor group includes at least one bottom conductor of the primary conductive loop and at least one bottom conductor of the secondary conductive loop. The top conductors have greater edgeside coupling along the first edgesides as compared to the second edgesides.

In a further embodiment, a planar electronic device is provided including a planar substrate having a cavity configured to receive a ferrite material body therein. The planar substrate has an island inside of the cavity and a shell outside of the cavity. The planar substrate has a top side and a bottom side. Shell conductive vias extend through the shell. Island conductive vias extend through the island. The island conductive vias include outer vias closer to the cavity and inner vias closer to a center of the island. Adjacent inner vias define inner via groups and axes through the inner via groups are non-perpendicular with respect to each other axis. Top conductors are provided on the top side of the planar substrate electrically connected to corresponding shell and island conductive vias. Bottom conductors are provided on the bottom side of the planar substrate electrically connected to corresponding conductive vias. The top conductors, bottom conductors, shell conductive vias and island conductive vias define a primary conductive loop and a secondary conductive loop.

### BRIEF DESCRIPTION OF THE DRAWINGS

FIG. 1 is a perspective view of one embodiment of a planar electronic device.

FIG. 2 is a top view of the planar electronic device.

FIG. 3 is a cross-sectional view of the planar electronic device along line A-A shown in FIG. 2.

FIG. 4 is a top view of the planar electronic device showing an exemplary layout of top conductors.

FIG. 5 is a bottom view of the planar electronic device showing an exemplary layout of bottom conductors.

FIG. 6 is a top view of a planar electronic device formed in accordance with an exemplary embodiment.

FIG. 7 illustrates a portion of a planar electronic device formed in accordance with an exemplary embodiment.

FIG. 8 illustrates different embodiments of staggering of vias and conductors for planar electronic devices.

### DETAILED DESCRIPTION OF THE INVENTION

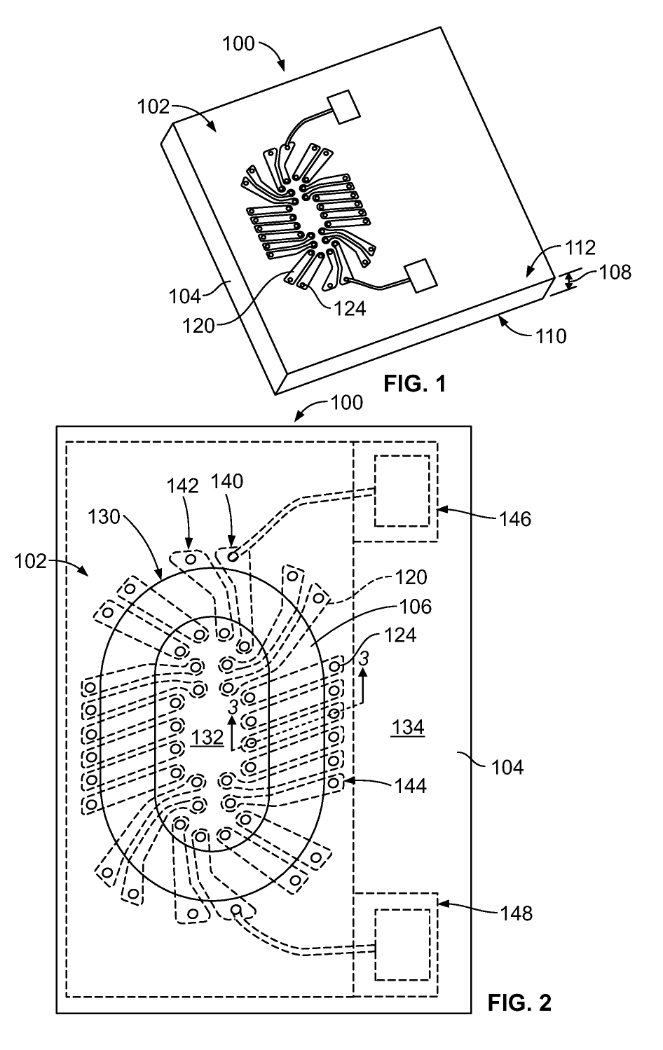

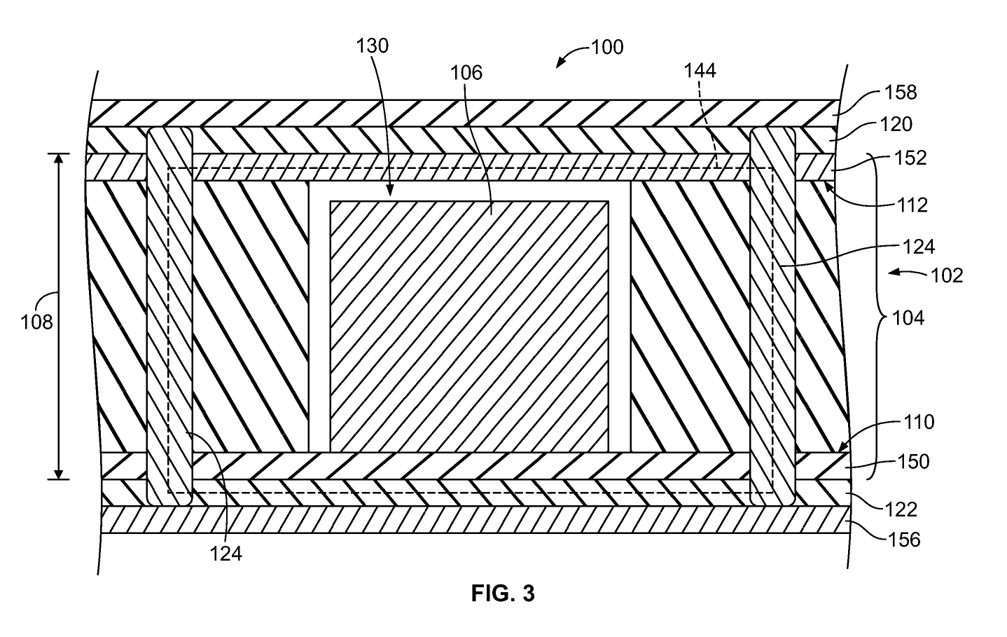

FIG. 1 is a perspective view of one embodiment of a planar electronic device 100 having a magnetic component 102. The magnetic component 102 shown in FIG. 1 is a transformer device. Alternatively, the magnetic component 102 may be or include another electronic device or component, such as an inductor, filter, balun, coupler, and the like, that includes a ferrite body or other magnetic material. The magnetic component 102 is disposed in a planar dielectric or non-conductive substrate 104. The substrate 104 holds a ferrite material body 106 (shown in FIG. 2). The illustrated magnetic component 102 has an oval shape, but alternatively may have a different shape, such as a circular shape.

The substrate 104 has a thickness dimension 108 that is measured between a lower side 110 and an opposite upper side 112 of the substrate 104. As used herein, the terms “lower” and “upper” or “top” and “bottom” are used to refer to the opposite sides of the substrate 104. The use of the terms “lower” and “upper” or “top” and “bottom” are not meant to limit or require a single, specific orientation of the substrate 104. For example, the substrate 104 may be flipped over such that the upper side 112 is below the lower side 110.

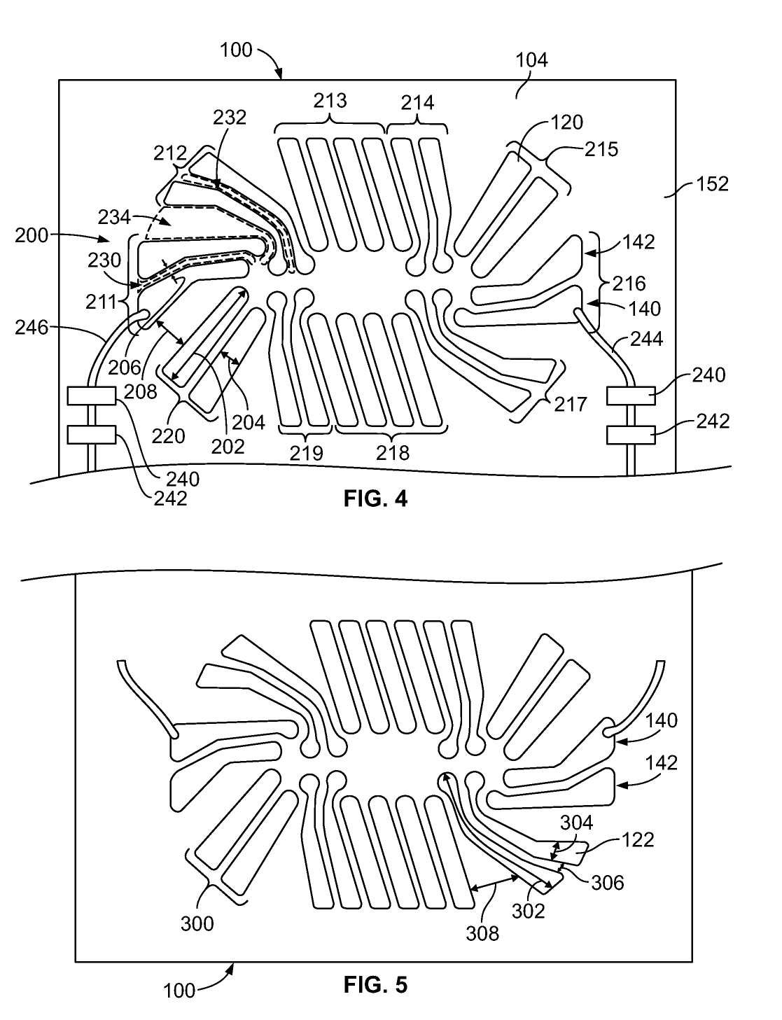

For each magnetic component 102, several top conductors 120 are disposed on the upper side 112 of the substrate 104, and several bottom conductors 122 (shown in FIG. 3) are disposed on the lower side 110 of the substrate 104. The bottom conductors 122 may be the same size and/or shape as the top conductors 120. The substrate 104 includes conductive vias 124 that extend through the substrate 104 from the upper side 112 of the substrate 104 to the lower side 110 of the substrate 104. The vias 124 are filled or plated with a conductive material to provide conductive pathways through the substrate 104. Opposite ends of each via 124 are conductively coupled with the top conductors 120 and the bottom conductors 122 on the substrate 104. The vias 124, top conductors 120, and bottom conductors 122 form looping or winding conductive pathways that wrap around the ferrite material body 106 (shown in FIG. 2) that is disposed within the substrate 104.

FIG. 2 is a top view of the planar electronic device 100 showing the top conductors 120 in phantom view so that the location of the ferrite material body 106 in the magnetic component 102 may be more easily seen. The substrate 104 includes a cavity 130 that receives the ferrite material body 106. The substrate 104 includes an island 132 inside the cavity 130 that defines an inside wall of the cavity 130. The substrate 104 includes a shell 134 outside of the cavity 130 and defining an outside wall of the cavity 130. In the illustrated embodiment, the cavity 130 is oval-shaped, however other shapes are possible in alternative embodiments. The ferrite material body 106 is oval-shaped in correspondence with the oval-shaped cavity 130. The island 132 is received in the hole in the center of the ferrite material body 106.

The top conductors 120 are conductively coupled with the vias 124 at opposite ends of the top conductors 120. The vias 124 are located on both sides of the ferrite material body 106 (e.g., inside and outside). As described above, the vias 124 include conductive material and are conductively coupled with the bottom conductors 122 (shown in FIG. 3) disposed on the lower side 110 (shown in FIG. 1) of the substrate 104. The top conductors 120, the vias 124, and the bottom conductors 122 are arranged as coils that loop or wrap multiple times around the ferrite material body 106.

In the illustrated embodiment, the top conductors 120, the vias 124, and the bottom conductors 122 form two separate coils that may be referred to as primary and secondary conductive loops 140, 142. Each of the reference numbers 140, 142 in FIG. 2 point to dashed boxes that encircle a different conductive loop of the magnetic component 102. Each conductive loop 140, 142 includes several turns 144 around the ferrite material body 106. The turn 144 may be any segment of the loop 140, 142, including a segment less than 360°. A turn of the primary conductive loop 140 may be referred to as a primary turn and a turn of the secondary conductive loop 140 may be referred to as a secondary turn. The combination of the conductive loops 140, 142 and the ferrite material body 106 form the magnetic component 102. The conductive loops 140, 142 that wrap around the ferrite material body 106 are not conductively coupled with each other. Energy is coupled from the conductive loops 140, 142 through the ferrite material body 106 by magnetic induction at lower frequencies and by interwinding capacitance at higher frequencies. The spacings between the conductive loops 140, 142 are restricted due to limitations of etching processes or other deposition processes. The spacings between the conductive loops 140, 142 are restricted due to the specification of high dielectric isolation between the primary and secondary loops. In one embodiment, the first conductive loop 140 of the magnetic component 102 receives electric power from a first circuit 146, and the second conductive loop 142 of the magnetic component 102 is conductively coupled with a second circuit 148.

The first and second conductive loops 140, 142 can be inductively coupled with each other by the ferrite material body 106 such that electric current passing through the first conductive loop 140 is inductively transferred to the second conductive loop 142. For example, a varying electric current passing through the first conductive loop 140 can create a varying magnetic flux in the ferrite material body 106. The varying magnetic flux generates a varying magnetic field in the second conductive loop 142. The varying magnetic field induces a varying electromotive force, or voltage, in the second conductive loop 142. The second conductive loop 142 transfers the induced voltage to the second circuit 148.

FIG. 3 is a cross-sectional view of the planar electronic device 100 along line 3-3 shown in FIG. 2. The planar electronic device 100 is a laminate structure having several layers disposed on top of each other. The substrate 104 can include or be formed from a dielectric material, such as a glass-filled epoxy (e.g., FR-4) suitable for a printed circuit board (PCB), a thermoset material, or a thermoplastic material. Alternatively, another rigid or semi-rigid material may be used for the substrate 104. The cavity 130 extends at least partially through the substrate 104 and provides an opening in which the ferrite material body 106 is disposed.

The substrate 104 includes lower and upper cover layers 150, 152 at the lower and upper sides 110, 112. The cover layers 150, 152 cover the lower and upper sides 110, 112 and the cavity 130. Optionally, other layers may be provided between the cover layers 150, 152 and the cavity 130. The lower and upper cover layers 150, 152 may be attached to the middle body of the substrate 104 using adhesive layers. The adhesive layers may be formed by depositing an epoxy, a low stress epoxy, a thermoplastic, a high temperature thermoplastic, or a high lateral flow ceramic filled hydrocarbon material. Alternatively, a different material may be used. The adhesive layers may be cured to provide mechanical stability to the substrate 104. Optionally, the lower and upper cover layers 150, 152 may comprise different materials and/or have different properties. In an exemplary embodiment, the cavity 130 may be filled with low stress epoxy. In an alternative embodiment, the ferrite material body 106 may be embedded in an air cavity.

In an exemplary embodiment, the cover layers 150, 152 are manufactured from a high permittivity material and the high permittivity material increases primary to secondary capacitance. In an exemplary embodiment, the top conductors 120 are secured to the upper cover layer 152 and the bottom conductors 122 are secured to the lower cover layer 150. The top and bottom conductors 120, 122 may be secured to the cover layers 152, 150 by depositing conductive layers (e.g., metal or metal alloy layers) onto the cover layers 152, 150. In one embodiment, the conductors 120, 122 are formed by selectively depositing copper or a copper alloy onto the cover layers 152, 150. One or more additional conductive or metal layers may be added by laminating additional upper and/or lower cover layers 152, 150 on or outside of the top and/or bottom conductors 120, 122 and then depositing additional conductive layers (such as additional top and/or bottom conductors 120, 122) on the additional cover layers.

As shown in FIG. 3, the vias 124 vertically extend through the substrate 104. For example, the vias 124 extend from the top conductor 120 to the bottom conductor 122 and pass throughout the entire thickness dimension 108 of the substrate 104. The vias 124 are filled with a conductive material, such as a metal or metal alloy, in the illustrated embodiment. Alternatively, the interior surfaces of the vias 124 may be plated with a conductive material. As described above, the vias 124 provide a conductive pathway that conductively couples the top and bottom conductors 120, 122. As shown in the cross-sectional view of FIG. 3, the top conductor 120, the bottom conductor 122, and the vias 124 form a single turn 144 that encircles or extends around the ferrite material body 106.

Lower and upper mask layers 156, 158 may be provided outside of the bottom and top conductors 122, 120. In one embodiment, the mask layers 156, 158 are solder mask layers that prevent exposure of portions of the bottom and top conductors 122, 120 to deposition of solder. For example, the mask layers 156, 158 may be provided on portions of the bottom and top conductors 122, 120 to prevent solder from being deposited on those portions. In an exemplary embodiment, the mask layers 156, 158 are manufactured from a high permittivity material and the high permittivity material increases primary to secondary capacitance. Alternatively, the mask layers 156, 158 may not be included in the magnetic component 102.

FIG. 4 is a top view of the planar electronic device 100 showing an exemplary layout of the top conductors 120. Adjacent top conductors 120 are arranged in top conductor groups 200. Each top conductor group 200 includes at least one top conductor 120 from the primary conductive loop 140 (shown in FIG. 2) and at least one top conductor 120 from the secondary conductive loop 142 (shown in FIG. 2).

The top conductors 120 within each top conductor group 200 have substantially similar layouts. The layouts are defined by the size and shape of the top conductors 120. The layouts are defined by a longitudinal length 202, a lateral width 204 and a surface area of the top conductors 120. The layouts are defined by intragroup spacing 206 and intergroup spacing 208 between adjacent top conductors 120. In the illustrated embodiment, the layouts of the top conductors 120 of adjacent top conductor groups 200 are different. By having the layouts of the top conductors 120 within the same top conductor group 200 substantially similar, the windings have improved performance. By having the layouts of the top conductors 120 within the same top conductor group 200 substantially similar, the primary and secondary windings are substantially equal in length. The differential to common mode and common mode to differential conversions are reduced, as compared to layouts that have unequal primary and secondary windings. The top conductors 120 sacrifice capacitance and capacitive coupling between adjacent top conductors 120, such as top conductors 120 in different groups 200, to achieve substantially similar layouts. Such capacitance and capacitive coupling may be compensated for by use of high permittivity materials on cover layers of the substrate 104 and/or the use of metal petals that increase the capacitance between the primary and secondary windings.

The layout of the top conductors 120 is illustrative and alternative embodiments may have alternative layouts. Having the top conductors 120 grouped together and making the top conductors 120 within each group 200 substantially similar provides better performance for the planar electronic device 100. In the illustrated embodiment, the planar electronic device 100 includes a first top conductor group 211, a second top conductor group 212, a third top conductor group 213, a fourth top conductor group 214, a fifth top conductor group 215, a sixth top conductor group 216, a seventh top conductor group 217, an eighth top conductor group 218, a ninth top conductor group 219, and a tenth top conductor group 220. Any number of groups may be provided in alternative embodiments.

In the illustrated embodiment, the third and eighth top conductor groups 213, 218 include four top conductors 120, for example two primary turns and two secondary turns, while the other top conductor groups 211, 212, 214, 215, 216, 217, 219, 220 include two top conductors 120, for example a single primary turn and a single secondary turn.

In the illustrated embodiment, the top conductors 120 of the second, fourth, seventh and ninth top conductor groups 212, 214, 217, 219 are relatively long, while the top conductors 120 of the first, third, fifth, sixth, eighth and tenth groups 211, 213, 215, 216, 218, 220 are relatively short.

In the illustrated embodiment, the intragroup spacings 206 tend to be narrower than the intergroup spacings 208. For example, the intergroup spacing 208 between the first and second top conductor groups 211, 212 is significantly greater than the intragroup spacing 206 of the first top conductor group 211 and is significantly greater than the intragroup spacing 206 of the second top conductor group 212. The intragroup spacing 206 of the first top conductor group 211 has a first intragroup surface area 230. The intragroup spacing 206 of the second top conductor group 212 has a second intragroup surface area 232. The intergroup spacing 208 between the first and second top conductor groups 211, 212 has an intergroup surface area 234. The intergroup surface area 234 is at least twice as large as the first intragroup surface area 230 and is at least twice as large as the second intragroup surface area 232. Designing the layouts to have the top conductors 120 substantially similar tends to make the intergroup surface area 234 larger than either of the first and second intragroup surface areas 230, 232 because consideration is given to the top conductors 120 of the individual groups as opposed to maximizing the footprint and filling as much of the footprint with the top conductors 120 to maximize capacitance between all of the top conductors 120. While the layout of the top conductors 120 may not maximize the capacitance because the intergroup spacings 208 are relatively large, designing the layout of the top conductors 120 to ensure the top conductors 120 within each group 200 are substantially similar provides primary and secondary windings that have improved electrical performance as compared to designs having the primary and secondary windings unequal (e.g. different lengths, different widths and/or having different surface areas).

In an exemplary embodiment, return loss and insertion loss degradation, which may occur due to the particular layout of the top conductors 120, may be improved by using shunt capacitors 240 and series inductors 242 at the input 244 of the first circuit 140 and at the output 246 of the second circuit 142. Tuning elements other than the shunt capacitors 240 and the series inductors 242 may be used to improve the return loss or other electrical characteristics of the first and second circuits 140, 142. The return loss and other electrical characteristics may be improved by increasing the capacitance between the primary and the secondary windings, such as by using high permittivity materials around the top conductors 120, such as on the upper cover layer 152 (shown in FIG. 3). Other cover layers may be provided, and the cover layers may be metalized (e.g., may include metal petals deposited thereon that are aligned with corresponding top conductors 120) to provide additional capacitive coupling between the top conductors 120 of the primary and secondary windings.

FIG. 5 is a bottom view of the planar electronic device 100 showing an exemplary layout of the bottom conductors 122. Adjacent bottom conductors 122 are arranged in bottom conductor groups 300. Each bottom conductor group 300 includes at least one bottom conductor 122 from the primary conductive loop 140 (shown in FIG. 2) and at least one bottom conductor 122 from the secondary conductive loop 142 (shown in FIG. 2). The bottom conductors 122 within each bottom conductor group 300 have substantially similar layouts. By having the layouts of the bottom conductors 122 within the same bottom conductor group 300 substantially similar, the windings have improved performance. By having the layouts of the bottom conductors 122 within the same bottom conductor group 300 substantially similar, the primary and secondary windings are substantially equal in length.

The bottom conductors 122 within each bottom conductor group 300 have substantially similar layouts. The layouts are defined by the size and shape of the bottom conductors 122. The layouts are defined by a longitudinal length 302, a lateral width 304 and a surface area of the bottom conductors 122. The layouts are defined by intragroup spacings 306 and intergroup spacings 308 between adjacent bottom conductors 122. In the illustrated embodiment, the layouts of the bottom conductors 122 of adjacent bottom conductor groups 300 are different.

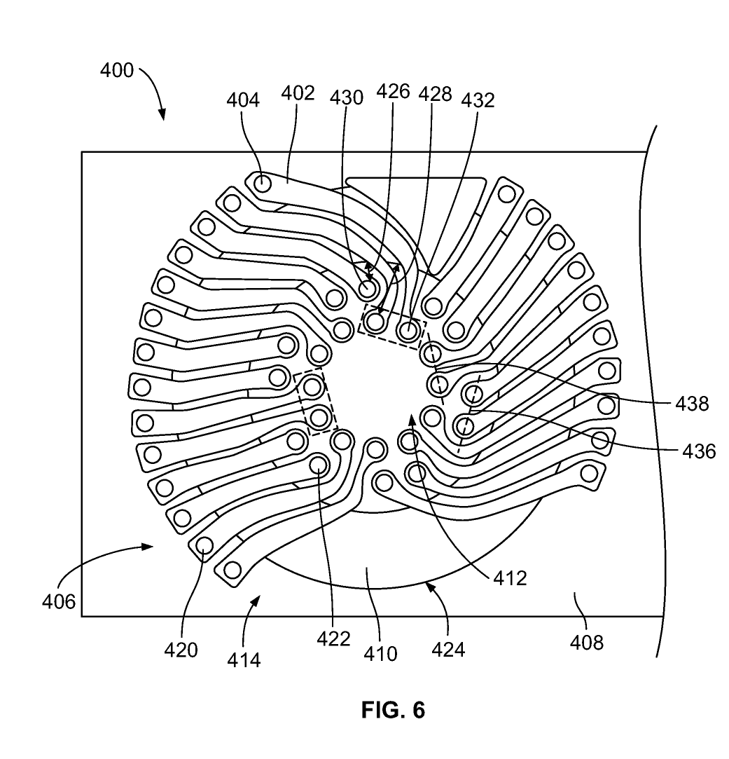

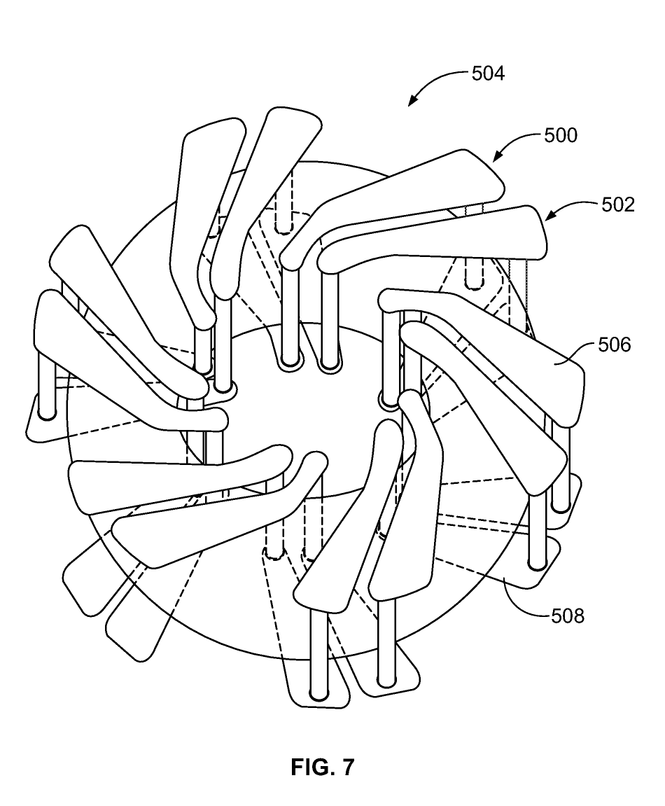

FIG. 6 is a top view of a planar electronic device 400 formed in accordance with an exemplary embodiment. The planar electronic device 400 is similar to the planar electronic device 100, however the planar electronic device 400 has a different layout of top conductors 402 and vias 404. The planar electronic device 400 includes a magnetic component 406 disposed in a planar dielectric or non-conductive substrate 408. The substrate 408 holds a ferrite material body 410 (shown in phantom) having a circular shape.

The substrate 408 includes an island 412 of substrate material inside the ferrite material body 410 and a shell 414 of substrate material outside of the ferrite material body 410. The ferrite material body 410 is ring-shaped with the island 412 being received in the hole in the center of the ferrite material body 410.

The top conductors 402 are conductively coupled with corresponding vias 404 at opposite ends of the top conductors 402. The vias 404 are located on both sides of the ferrite material body 410 (e.g., inside and outside) and define shell conductive vias 420 and island conductive vias 422. The shell conductive vias 420 extend through the shell 414 and the island conductive vias 422 extending through the island 412.

In an exemplary embodiment, the shell conductive vias 420 are approximately uniformly spaced apart from the ferrite material body 410 and a cavity 424 that holds the ferrite material body 410. Alternatively, the shell conductive vias 420 may be non-uniformly spaced from the ferrite material body 410 and the cavity 424. For example, adjacent shell conductive vias 420 may be staggered in their spacing from the ferrite material body 410 and the cavity 424, or groups such as pairs of shell conductive vias 420 may be staggered in their spacing from the ferrite material body 410 and the cavity 424.

In an exemplary embodiment, the island conductive vias 422 are spaced apart from the ferrite material body 410 and the cavity 424 by non-uniform distances, examples of which are shown with reference numerals 426, 428 representing different distances. In the illustrated embodiment, adjacent island conductive vias 422 are grouped in pairs (however any number of island conductive vias 422 may be grouped) with adjacent pairs spaced at different distances 426, 428 from the ferrite material body 410 and the cavity 424. The island conductive vias 422 include outer vias 430 closer to the cavity 424 and inner vias 432 further from the cavity 424 and closer to a center of the island 412. Optionally, all of the inner vias 432 are associated with the primary conductive loop and all of the outer vias 430 are associated with the secondary conducive loop.

In an exemplary embodiment, each pair of outer vias 430 is disposed along a respective outer via axis 436 which is defined by bi-sectors of the pair of outer vias 430, and each pair of inner vias 432 is disposed along a respective inner via axis 438 which is defined by bi-sectors of the pair of inner vias 432. In an exemplary embodiment, the outer via axes 436 are oriented such that no outer via axis 436 is oriented perpendicular to any other outer via axis 436. In an exemplary embodiment, the inner via axes 438 are oriented such that no inner via axis 438 is oriented perpendicular to any other inner via axis 438. In an exemplary embodiment, the outer via axes 436 are oriented such that no outer via axis 436 is oriented perpendicular to any inner via axis 438. In an exemplary embodiment, the inner via axes 438 are oriented such that no inner via axis 438 is oriented perpendicular to any outer via axis 436. Having the axes 436, 438 oriented at non-perpendicular orientations reduces wicking between via pairs caused by glass weave construction of the substrate material (e.g. FR-4). Having the axes 436, 438 oriented at non-perpendicular orientations may provide yield improvements. In an exemplary embodiment, the island conductive vias 422 are positioned in different planes from the glass weave of the material of the island 420 to prevent excess dielectric breakdown during moisture loading, plating steps, and wet chemistry processes. Having the axes 436, 438 oriented at non-perpendicular orientations allows for the island conductive vias 422 to be positioned in different planes from the glass weave.

FIG. 7 illustrates primary and secondary conductive loops 500, 502 of another planar electronic device 504. A substrate and one or more cover layers may be provided to provide capacitance compensation for the primary and secondary conductive loops 500, 502. In the illustrated embodiment, top conductors 506 and bottom conductors 508 are grouped together in pairs. In the illustrated embodiment, one top conductor 506 of each group is part of the primary conductive loop 500, and the other top conductor 506 of each group is part of the secondary conductive loop 500. Similarly, one bottom conductor 508 of each group is part of the primary conductive loop 500, and the other bottom conductor 508 of each group is part of the secondary conductive loop 500. The top and bottom conductors 506, 508 within each group are spaced closer together than a spacing between the top conductors 506 of adjacent groups and a spacing between the bottom conductors 508 of adjacent groups.

In an exemplary embodiment, top and/or bottom cover layers (not shown) are used to increase capacitive coupling between the conductors 506, 508 of the primary and secondary conductive loops 500, 502. The top and/or bottom cover layers may be manufactured from a material having a high relative permittivity. The top and/or bottom cover layers may be metalized, such as including one or more metal petals, to increase capacitive coupling between the conductors 506, 508 of the primary and secondary conductive loops 500, 502.

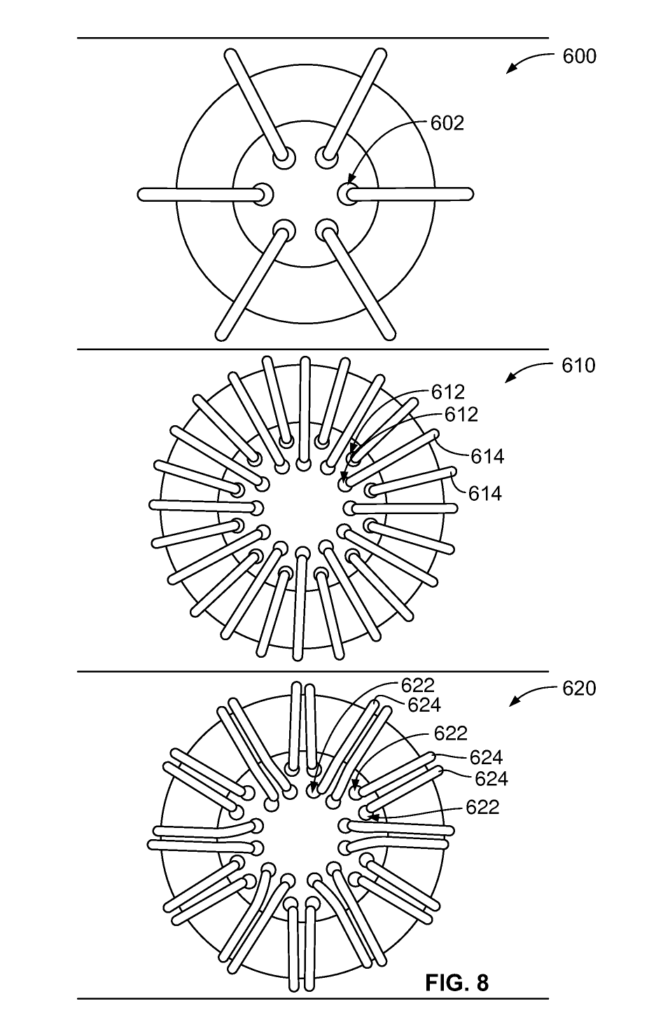

FIG. 8 illustrates different embodiments of staggering of vias and conductors for planar electronic devices. At 600, no staggering of vias 602 is provided. At 610, every other via 612 and associated conductor 614 are staggered. At 620, the vias 622 and conductors 624 are staggered in pairs. Primary and secondary conductive loops are provided. A substrate and one or more cover layers may be provided to provide capacitance compensation for the primary and secondary conductive loops.

The conductors 624 are grouped together in pairs. In the illustrated embodiment, one conductor 624 of each group is part of the primary conductive loop, and the other conductors 624 of each group is part of the secondary conductive loop. The conductors 624 within each group are spaced closer together than a spacing between the conductors 624 of adjacent groups.

In an exemplary embodiment, top and/or bottom cover layers (not shown) are used to increase capacitive coupling between the conductors 624 of the primary and secondary conductive loops. The top and/or bottom cover layers may be manufactured from a material having a high relative permittivity. The top and/or bottom cover layers may be metalized, such as including one or more metal petals, to increase capacitive coupling between the conductors 624 of the primary and secondary conductive loops.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. A planar electronic device comprising:
a planar substrate having a cavity configured to receive a ferrite material body therein, the planar substrate having a top side and a bottom side;
conductive vias extending through the substrate;
top conductors on the top side of the planar substrate and electrically connected to corresponding conductive vias, adjacent top conductors defining top conductor groups; and
bottom conductors on the bottom side of the planar substrate and electrically connected to corresponding conductive vias, adjacent bottom conductors defining bottom conductor groups;
wherein the top conductors, bottom conductors and conductive vias define a primary conductive loop and a secondary conductive loop, the top conductor group including at least one top conductor of the primary conductive loop and at least one top conductor of the secondary conductive loop, the bottom conductor group including at least one bottom conductor of the primary conductive loop and at least one bottom conductor of the secondary conductive loop;
wherein the top conductors within each group have substantially similar layouts that are different from layouts of the top conductors of the immediately adjacent groups, and the bottom conductors within each group have substantially similar layouts that are different from layouts of the bottom conductors of the immediately adjacent groups.

2. The planar electronic device of claim 1, wherein the layout comprises a longitudinal length, a lateral width and a surface area.

3. The planar electronic device of claim 1, wherein the layout comprises a size and a shape.

4. The planar electronic device of claim 1, wherein the layout of the top conductors comprises an intergroup spacing and an intragroup spacing between adjacent top conductors, the intergroup spacing being different than the intragroup spacing.

5. The planar electronic device of claim 1, wherein the top conductor groups comprise a first group, a second group and a third group, the top conductors of the first group having a first longitudinal length, the top conductors of the second group having a second longitudinal length, the top conductors of the third group having a third longitudinal length, the second longitudinal length being longer than the first longitudinal length and the third longitudinal length.

6. The planar electronic device of claim 1, wherein the top conductor groups comprise a first group and a second group adjacent the first group, the top conductors of the first group having a first intragroup spacing having a first intragroup surface area, the top conductors of the second group having a second intragroup spacing having a second intragroup surface area, and an intergroup spacing is defined between the nearest top conductors of the first and second groups, the intergroup spacing having an intergroup surface area, the intergroup surface area being at least twice as large as the first intragroup surface area and at least twice as large as the second intragroup surface area.

7. The planar electronic device of claim 1, wherein the cavity has a non-circular geometry.

8. The planar electronic device of claim 1, wherein the top conductors each have a first edgeside facing an adjacent top conductor within the corresponding group and a second edgeside facing the adjacent top conductor within the adjacent group, the top conductors having greater edgeside coupling along the first edgesides as compared to the second edgesides.

9. The planar electronic device of claim 1, wherein the planar substrate includes an island inside the cavity and a shell outside the cavity, the conductive vias comprising shell conductive vias extending through the shell and island conductive vias extending through the island, the island conductive vias comprising outer vias closer to the cavity and inner vias closer to a center of the island, wherein adjacent inner vias define inner via pairs and wherein inner via axes through the inner via pairs are non-perpendicular with respect to each other inner via axis.

10. A planar electronic device comprising:
a planar substrate having a cavity configured to receive a ferrite material body therein, the planar substrate having a top side and a bottom side;
conductive vias extending through the substrate;
top conductors on the top side of the planar substrate and electrically connected to corresponding conductive vias, adjacent top conductors defining top conductor groups, the top conductors each having a first edgeside facing the adjacent top conductor within the corresponding group and a second edgeside facing the adjacent top conductor within the adjacent group; and
bottom conductors on the bottom side of the planar substrate and electrically connected to corresponding conductive vias;
wherein the top conductors, bottom conductors and conductive vias define a primary conductive loop and a secondary conductive loop, the top conductor group including at least one top conductor of the primary conductive loop and at least one top conductor of the secondary conductive loop, the bottom conductor group including at least one bottom conductor of the primary conductive loop and at least one bottom conductor of the secondary conductive loop;
wherein the top conductors have greater edgeside coupling along the first edgesides as compared to the second edgesides.

11. The planar electronic device of claim 10, wherein the layout comprises a longitudinal length, a lateral width and a surface area.

12. The planar electronic device of claim 10, wherein the layout of the top conductors comprises an intergroup spacing and an intragroup spacing between adjacent top conductors, the intergroup spacing being different than the intragroup spacing.

13. The planar electronic device of claim 10, wherein the top conductor groups comprise a first group, a second group and a third group, the top conductors of the first group having a first longitudinal length, the top conductors of the second group having a second longitudinal length, the top conductors of the third group having a third longitudinal length, the second longitudinal length being longer than the first longitudinal length and the third longitudinal length.

14. The planar electronic device of claim 10, wherein the top conductor groups comprise a first group and a second group adjacent the first group, the top conductors of the first group having a first intragroup spacing having a first intragroup surface area, the top conductors of the second group having a second intragroup spacing having a second intragroup surface area, and an intergroup spacing is defined between the nearest top conductors of the first and second groups, the intergroup spacing having an intergroup surface area, the intergroup surface area being at least twice as large as the first intragroup surface area and at least twice as large as the second intragroup surface area.

15. The planar electronic device of claim 10, wherein the planar substrate includes an island inside the cavity and a shell outside the cavity, the conductive vias comprising shell conductive vias extending through the shell and island conductive vias extending through the island, the island conductive vias comprising outer vias closer to the cavity and inner vias closer to a center of the island, wherein adjacent inner vias define inner via pairs and wherein inner via axes through the inner via pairs are non-perpendicular with respect to each other inner via axis.

16. A planar electronic device comprising:
a planar substrate having a cavity configured to receive a ferrite material body therein, the planar substrate having an island inside of the cavity and a shell outside of the cavity, the planar substrate having a top side and a bottom side;
shell conductive vias extending through the shell;
island conductive vias extending through the island, the island conductive vias comprising outer vias closer to the cavity and inner vias closer to a center of the island, wherein adjacent inner vias define inner via pairs, and wherein inner via axes through the inner via pairs are non-perpendicular with respect to each other inner via axis;
top conductors on the top side of the planar substrate and electrically connected to corresponding shell and island conductive vias; and
bottom conductors on the bottom side of the planar substrate and electrically connected to corresponding conductive vias;
wherein the top conductors, bottom conductors, shell conductive vias and island conductive vias define a primary conductive loop and a secondary conductive loop.

17. The planar electronic device of claim 16, wherein the layout comprises a longitudinal length, a lateral width and a surface area.

18. The planar electronic device of claim 16, wherein the layout of the top conductors comprises an intergroup spacing and an intragroup spacing between adjacent top conductors, the intergroup spacing being different than the intragroup spacing.

19. The planar electronic device of claim 16, wherein the top conductor groups comprise a first group, a second group and a third group, the top conductors of the first group having a first longitudinal length, the top conductors of the second group having a second longitudinal length, the top conductors of the third group having a third longitudinal length, the second longitudinal length being longer than the first longitudinal length and the third longitudinal length.

20. The planar electronic device of claim 16, wherein the top conductor groups comprise a first group and a second group adjacent the first group, the top conductors of the first group having a first intragroup spacing having a first intragroup surface area, the top conductors of the second group having a second intragroup spacing having a second intragroup surface area, and an intergroup spacing is defined between the nearest top conductors of the first and second groups, the intergroup spacing having an intergroup surface area, the intergroup surface area being at least twice as large as the first intragroup surface area and at least twice as large as the second intragroup surface area.
